(19) United States
(12) Patent Application Publication
(10) Pub. No.: US 2024/0429282 A1
(43) Pub. Date: Dec. 26, 2024

(54) SEMICONDUCTOR DEVICE

(71) Applicant: Mitsubishi Electric Corporation, Tokyo (JP)

(72) Inventors: Yusuke MIYATA, Tokyo (JP); Yuji EBIIKE, Tokyo (JP); Hayato OKAMOTO, Tokyo (JP); Tomohiro TAMAKI, Tokyo (JP); Kazuya KONISHI, Tokyo (JP); Munetaka NOGUCHI, Tokyo (JP)

(73) Assignee: Mitsubishi Electric Corporation, Tokyo (JP)

(21) Appl. No.: 18/637,017

(22) Filed: Apr. 16, 2024

(30) Foreign Application Priority Data
Jun. 22, 2023 (JP) 2023-102361

(51) Int. Cl. H01L 29/06; H01L 29/10; H01L 29/32; H01L 29/739

(52) U.S. Cl. CPC H01L 29/0696; H01L 29/1095; H01L 29/32; H01L 29/7397

(57) ABSTRACT

A plan layout on a semiconductor substrate has a distribution of threshold voltages for switching. In a case where a histogram is defined by a plurality of bins each having a bin width of 100 mV for the threshold voltages and a plurality of frequencies corresponding to areas in the plan layout belonging to the respective bins, the plan layout includes a plurality of regions belonging to different bins of the plurality of bins. The plurality of regions include first to third regions. The histogram has, based on a normal distribution, a distribution tailed on a low voltage side contiguously with the normal distribution.

### BACKGROUND OF THE INVENTION

### Field of the Invention

The present disclosure relates to semiconductor devices and, in particular, to insulated gate bipolar transistors or reverse-conducting insulated gate bipolar transistors.

### Description of the Background Art

According to WO 2012/141121, in a semiconductor device having a power active element, such as a power MOSFET, which has an insulating gate, a sub-active cell region, which has a threshold voltage lower than that of other regions and occupies a relatively narrow area, is provided in an active cell region. The above-mentioned document claims that generation of an overshoot voltage can be reduced as the sub-active cell region is turned on first in turn-on.

According to Japanese Patent Application Laid-Open No. 2016-154218, a semiconductor device includes transistor cells and enhancement cells. Each transistor cell includes a body zone that forms a first pn junction with a drift structure. The transistor cell forms an inversion channel in the body zone when a first control signal exceeds a first threshold. A delay unit generates a second control signal whose trailing edge is delayed with respect to a trailing edge of the first control signal. The enhancement cells form inversion layers in the drift structure when the second control signal falls below a second threshold lower than the first threshold.

In technology disclosed in WO 2012/141121 described above, simply providing the sub-active cell region is likely to cause an increase in deviation from switching characteristics originally required by a user of the semiconductor device.

In technology disclosed in Japanese Patent Application Laid-Open No. 2016-154218 described above, different types of gate electrodes are formed in different types of cells, and delay signals corresponding to the cells are transmitted. One or more of the cells are thus turned off first to promote ejection of carriers. This can reduce a turn-off loss. It is believed that a configuration to provide the cells with different control signals can be modified to produce various effects not limited to the effect of reducing the turn-off loss as described above. For example, it is believed that radiated noise from the semiconductor device can be suppressed by suppressing a rapid rise of a current in turn-on. The semiconductor device, however, is required to include a plurality of types of control pads (gate pads) to receive a plurality of types of control signals. As a result, an effective area for the semiconductor device is greatly reduced.

### SUMMARY

The present disclosure has been conceived to solve a problem as described above, and it is one object of the present disclosure to provide a semiconductor device allowing for suppression of a rapid rise of a current in turn-on of the semiconductor device without greatly reducing an effective area of the semiconductor device.

One aspect according to the present disclosure is a semiconductor device being an insulated gate bipolar transistor or a reverse-conducting insulated gate bipolar transistor, and includes: a semiconductor substrate including a drift layer having a first conductivity type; and a gate structure including a gate electrode and a gate dielectric film for switching of the semiconductor device. A plan layout on the semiconductor substrate has a distribution of threshold voltages for the switching. In a case where a histogram is defined by a plurality of bins each having a bin width of 100 mV for the threshold voltages and a plurality of frequencies corresponding to areas in the plan layout belonging to the respective bins, the plan layout includes a plurality of regions belonging to different bins of the plurality of bins, the plurality of regions include first to third regions, and the histogram has, based on a normal distribution, a distribution tailed on a low voltage side contiguously with the normal distribution.

According to one aspect according to the present disclosure, the histogram has the distribution tailed on the low voltage side contiguously with the normal distribution. By utilizing the distribution, a rapid rise of a current in turn-on of the semiconductor device can be suppressed without greatly reducing an effective area of the semiconductor device.

These and other objects, features, aspects and advantages of the present disclosure will become more apparent from the following detailed description when taken in conjunction with the accompanying drawings.

### BRIEF DESCRIPTION OF THE DRAWINGS

FIG. 1 is a plan view for describing definition of a plurality of regions of a plan layout on a semiconductor substrate of a semiconductor device;

FIG. 2 is a graphical illustration of a histogram of a distribution of threshold voltages in a plan layout of a semiconductor device according to a first comparative example;

FIG. 3 is a plan view illustrating a configuration of the plan layout on a semiconductor substrate of the semiconductor device according to the first comparative example;

FIG. 4 is a graphical illustration of a histogram of a distribution of threshold voltages in a plan layout of a semiconductor device according to a second comparative example;

FIG. 5 is a graphical illustration of a histogram of a distribution of threshold voltages in a plan layout of a semiconductor device according to Embodiment 1;

FIG. 6 is a plan view illustrating a configuration of the plan layout on a semiconductor substrate of the semiconductor device according to Embodiment 1 or 2;

FIG. 7 is a plan view illustrating a modification of FIG. 6;

FIG. 8 is a graphical illustration of one example of transfer characteristics of the semiconductor device according to Embodiment 1;

FIG. 9 is a graphical illustration of a histogram of a distribution of threshold voltages in the plan layout of the semiconductor device according to Embodiment 2;

FIG. 10 is a graphical illustration of one example of transfer characteristics of the semiconductor device according to Embodiment 2;

FIG. 11 is a cross-sectional view schematically showing a configuration of a typical insulated gate bipolar transistor;

FIG. 12 is a cross-sectional view illustrating a configuration of an insulated gate bipolar transistor as the semiconductor device according to Embodiment 1 or 2;

FIG. 13 is a cross-sectional view illustrating a modification of FIG. 12;

FIG. 14 is a plan view illustrating a modification of FIG. 6;

FIG. 15 is a plan view illustrating a modification of FIG. 6;

FIG. 16 is a plan view illustrating a modification of FIG. 6;

FIG. 17 is a plan view illustrating a modification of FIG. 6; and

FIG. 18 is a graphical illustration of one contemplated example of a distribution of threshold voltages taken along the line XVIII-XVIII of FIG. 17.

### DESCRIPTION OF THE PREFERRED EMBODIMENTS

Embodiments will be described below with reference to the drawings. The same or corresponding portions bear the same reference signs in the drawings shown below, and description thereof is not repeated.

While description will be made below mainly on a case where a first conductivity type is an n type and a second conductivity type is a p type, the first conductivity type may be the p type and the second conductivity type may be the n type. As description related to an impurity concentration, “n⁻” indicates a lower impurity concentration than “n”, and “n⁺” indicates a higher impurity concentration than “n”. Similarly, “p⁻” indicates a lower impurity concentration than “p”, and “p⁺” indicates a higher impurity concentration than “p”.

While reference is made below only to a concentration of impurities determining a conductivity type, carbon being an element in the same group as silicon being a main component of a semiconductor may be contained. In a case where the magnetic field applied Czochralski (MCZ) method is applied, oxygen, boron, or nitrogen introduced concomitantly with the application may be contained.

Description will be made below on an active cell region including regions RG1 to RGn (first to n-th regions) corresponding to a distribution of threshold voltages for switching of a semiconductor device. A region having the largest area ratio to the active cell region is referred to as the region RG1, and the other regions are referred to as the region RG2, the region RG3, . . . , and the region RGn in descending order of area ratio. As for the regions RG1 to RGn, a histogram is defined as will be described in detail below. Before description of embodiments, definition of these regions is herein described first. A threshold voltage may specifically be defined as a gate voltage required to carry a current in an amount one ten-thousandth of a rated current density with a rated voltage being applied across a collector and an emitter. In this case, when the semiconductor device has a rated current density of 15 A/cm², for example, a gate voltage required to achieve a current density of 1.5 mA/cm² is the threshold voltage.

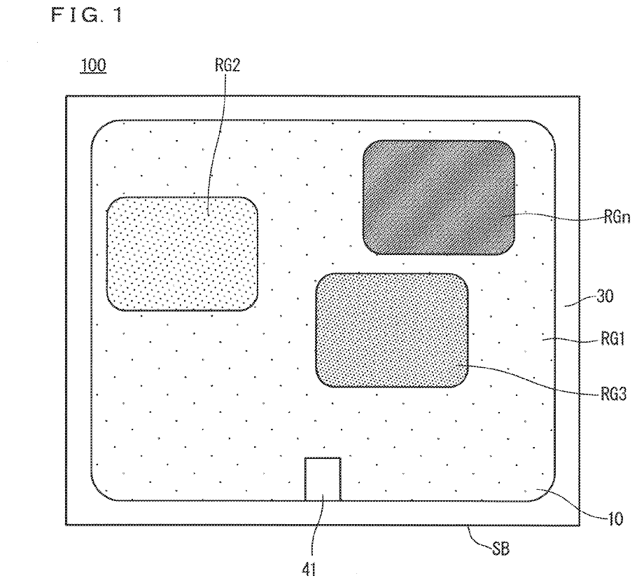

Matters common in embodiments and comparative examples described below will be described first with reference to FIG. 1. FIG. 1 is a plan view for describing definition of the plurality of regions RG1 to RGn of a plan layout on a semiconductor substrate SB of a semiconductor device 100. The semiconductor device 100 is an insulated gate bipolar transistor (IGBT) or a reverse-conducting insulated gate bipolar transistor (an RC-IGBT). The plan layout of the semiconductor device 100 includes an active IGBT cell region 10, a termination region 30, and a gate pad region 41. The semiconductor device 100 may include a diode region (not illustrated) in a region different from the active IGBT cell region 10.

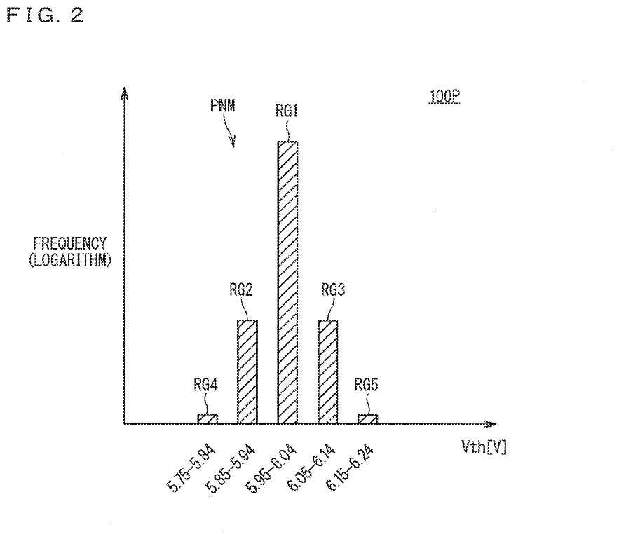

The plan layout has a distribution of threshold voltages for switching of the semiconductor device 100. A plurality of bins each having a bin width of 100 mV (i.e., a representative value ±50 mV) for the threshold voltages are defined. The plan layout includes the plurality of regions RG1 to RGn belonging to different bins of the plurality of bins. In other words, different regions belong to different bins, and one region belongs to one bin. The histogram (see FIG. 2, for example) is defined by these bins and a plurality of frequencies corresponding to areas in the plan layout belonging to the respective bins.

An excessive reduction in bin width endlessly increases the number of bins required to represent the distribution of threshold voltages and thus endlessly increases the number of regions. In contrast, an excessive increase in bin width decreases the number of regions to one in an extreme case regardless of the distribution of threshold voltages. A histogram having such an inappropriate bin width cannot be used to appropriately evaluate characteristics of the distribution of threshold voltages in the embodiments described below. The bin width is required to be appropriately selected to evaluate the characteristics so that the characteristics are distinct from conventionally naturally contemplated manufacturing variations, and 100 mV is one example of an appropriate value of the bin width according to the study of the present inventors. A range of a distribution of threshold voltages within the same substrate (i.e., the same chip) of a typical IGBT not intended to have a plurality of threshold voltages is 100 mV or less, so that, by setting the bin width to 100 mV, a histogram of the typical IGBT is assumed to have two or less bins (i.e., a voltage range ±100 mV) and is believed to have five bins corresponding to five regions RG1 to RG5 at most even if it is overestimated.

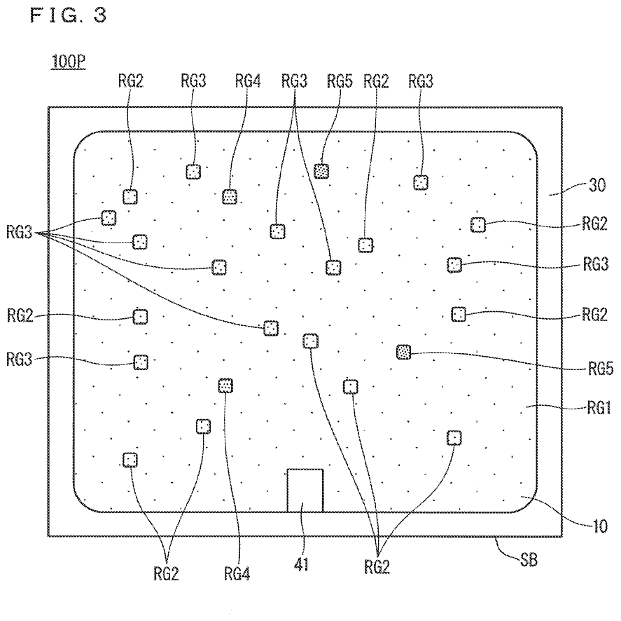

FIG. 2 is a graphical illustration of a histogram of a distribution of threshold voltages Vth in a plan layout of a semiconductor device 100P according to a first comparative example. FIG. 3 is a plan view illustrating a configuration of the plan layout on the semiconductor substrate SB of the semiconductor device 100P according to the first comparative example. The semiconductor device 100P has a distribution of threshold voltages represented by the five bins corresponding to the five regions RG1 to RG5 as described above. The distribution of the histogram of the semiconductor device 100P as a whole is substantially a normal distribution PNM. Frequencies of the respective bins of the histogram in FIG. 2 correspond to areas of the respective regions RG1 to RG5 in FIG. 3. For example, the region RG2 includes ten scattered minor portions in FIG. 3, and a total area of these minor portions corresponds to a frequency of a bin “5.85-5.94” [V] in FIG. 2. A distribution of threshold voltages containing unintentional manufacturing variations includes a region including randomly scattered minor portions as illustrated in FIG. 3, for example. It is appropriate to evaluate a distribution of characteristics of the semiconductor device in the plan layout for each unit cell of the semiconductor device. When the area of one unit cell is defined as a unit area, in a case where each of the above-mentioned minor portions forms one unit cell, the area of the minor portion corresponds to the unit area. In a case where a set of minor portions forms an island portion spanning a plurality of unit cells, the area of the minor portions has a value obtained by multiplying the unit area by the number of unit cells.

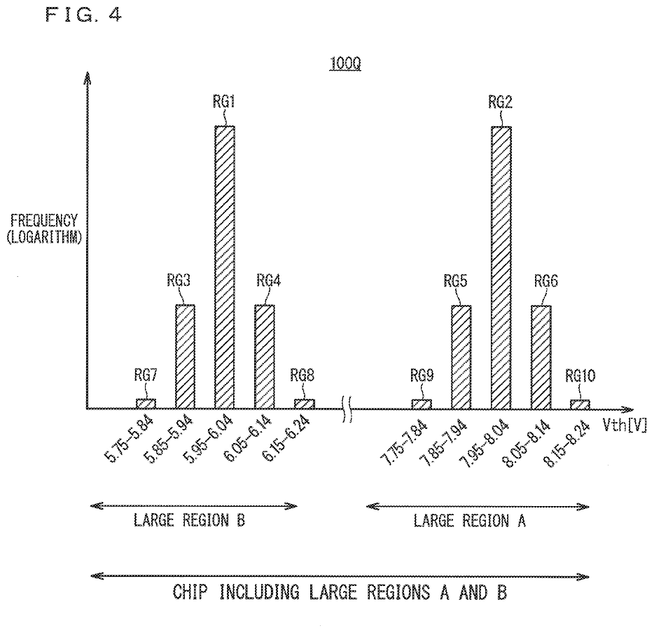

FIG. 4 is a graphical illustration of a histogram of a distribution of threshold voltages in a plan layout of a semiconductor device 100Q according to a second comparative example. This is believed to correspond to one example in a case where technology disclosed in WO 2012/141121 described above is simply applied. The semiconductor device 100Q is thus one example of a semiconductor device in which a plurality of regions having different threshold voltages are intentionally formed. Specifically, a large region A and a large region B are provided to correspond to respective intended threshold voltages as illustrated. In each of the large region A and the large region B, a distribution is substantially a normal distribution due to manufacturing variations and the like. On the other hand, the distribution in the large region A and the distribution in the large region B are not contiguous. In other words, the distribution in the large region A and the distribution in the large region B do not overlap each other. Not being contiguous (or not overlapping) herein means that one or more bins each having a frequency of zero are interposed between the large region A and the large region B.

As described above, the distribution in the large region A and the distribution in the large region B can be contiguous if evaluation is performed using a histogram having an excessively large bin width. A configuration in which the large region A and the large region B are separated by one or more bins each having a frequency of zero to the extent shown in the histogram of FIG. 4, however, is not due to manufacturing variations but due to an intention of a designer in the art, and evaluation is herein performed using a bin width of 100 mV to appropriately evaluate such characteristics.

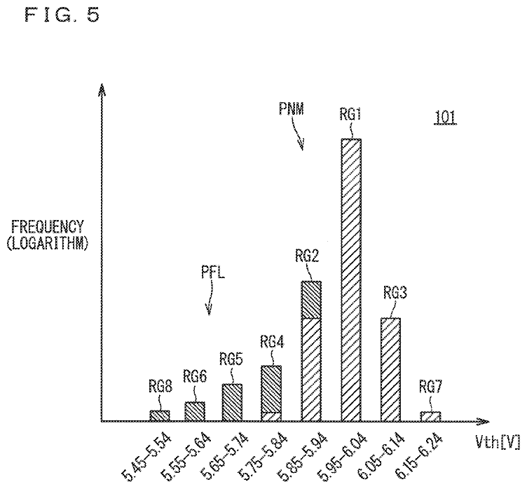

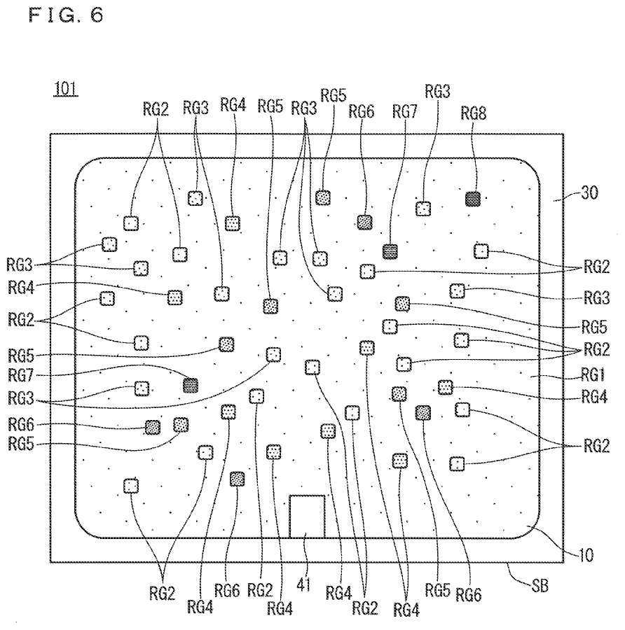

FIG. 5 is a graphical illustration of a histogram of a distribution of threshold voltages in a plan layout of a semiconductor device 101 according to Embodiment 1. FIG. 6 is a plan view illustrating a configuration of the plan layout on the semiconductor substrate SB of the semiconductor device 101.

The histogram (FIG. 5) of the semiconductor device 101 includes a substantially normal distribution PNM (a coarsely hatched region in FIG. 5) similarly to the histogram (FIG. 2) of the semiconductor device 100P while having a distribution skewed toward a low voltage side contiguously with the normal distribution PNM. Specifically, the histogram of the semiconductor device 101 has, in addition to the normal distribution PNM, a tailed distribution PFL (a finely hatched region in FIG. 5) being a distribution tailed on the low voltage side. In other words, the histogram has, based on the normal distribution PNM, the tailed distribution PFL tailed on the low voltage side contiguously with the normal distribution PNM. In contrast to the histogram of the semiconductor device 100Q (FIG. 4), the histogram of the semiconductor device 101 (FIG. 5) does not include one or more bins each having a frequency of zero interposed between bins each having a frequency being not zero. In FIG. 5, the tailed distribution PFL overlaps the normal distribution PNM on the low voltage side to form the distribution of the histogram. The histogram is thus contiguous.

The plan layout (FIG. 6) includes eight regions RG1 to RG8 belonging to different bins of a plurality of bins shown in FIG. 5. The regions RG1 to RGn of the plan layout are not limited to the eight regions RG1 to RG8, are only required to include at least the regions RG1 to RG3, and preferably include the regions RG1 to RG6. The same applies to Embodiment 2, which will be described below.

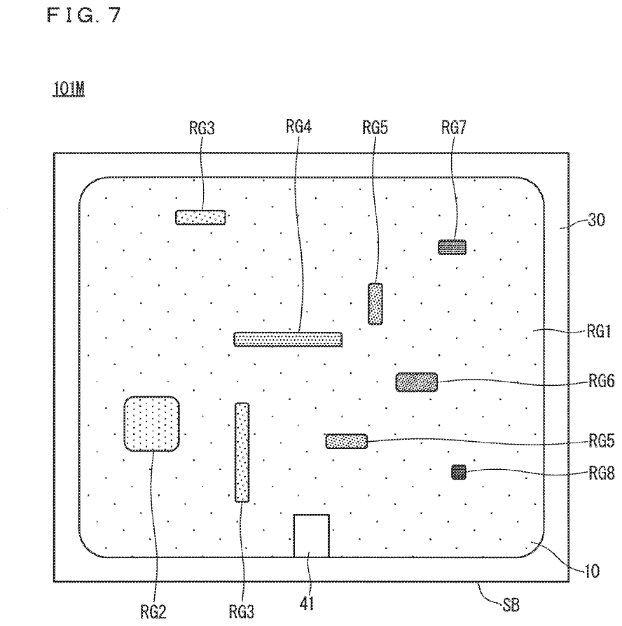

Frequencies of the respective bins of the histogram in FIG. 5 (and in FIG. 9 (according to Embodiment 2, which will be described below)) correspond to areas of the respective regions RG1 to RG8 in FIG. 6. In the semiconductor device 101 according to Embodiment 1 illustrated in FIG. 6, the region RG2 includes 16 scattered minor portions, for example, and a total area of these minor portions corresponds to a frequency of a bin “5.85-5.94” [V] in FIG. 5. A set of minor portions may form an island portion spanning a plurality of unit cells as in a semiconductor device 101M according to a modification illustrated in FIG. 7.

In an example shown in FIG. 5, the region RG8 being the lowest voltage portion of the tailed distribution PFL does not overlap the normal distribution PNM. The lowest voltage portion of the distribution of the histogram thus only includes the tailed distribution PFL. On the other hand, the region RG4 being the lowest voltage portion of the normal distribution PNM overlaps the tailed distribution PFL.

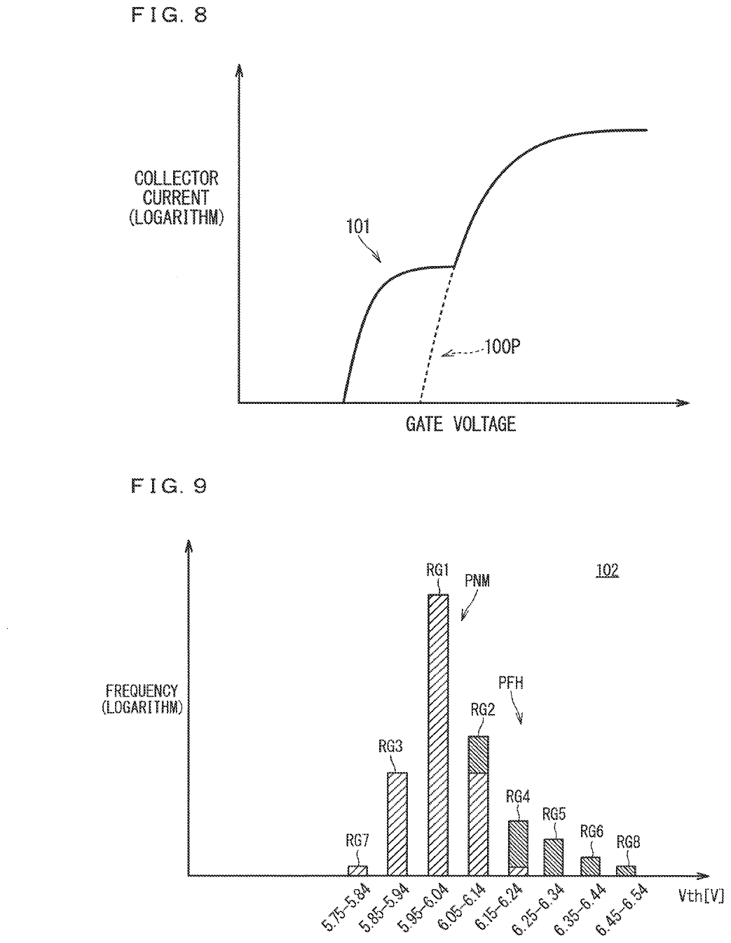

Referring to FIG. 8, a solid line in a graph indicates one example of transfer characteristics of the semiconductor device 101 (FIG. 5), and a dashed line in the graph indicates one example of transfer characteristics of the semiconductor device 100P (FIG. 2). The semiconductor device 101 (FIG. 5) has the tailed distribution PFL on the low voltage side, and cells in regions corresponding to the tailed distribution PFL are turned on first in on operation. Thus, a current starts to flow at a lower voltage than that in the semiconductor device 100P according to the comparative example. Referring to FIG. 5, as the gate voltage increases, the current gradually increases with the regions RG8, RG6, RG5, RG4, and RG2 being turned on in the stated order, rapidly increases with the largest region RG1 being turned on, and slightly increases and is saturated with the regions RG3 and RG7 being turned on in the stated order. FIG. 8 shows just one example, and a threshold voltage of the tailed distribution PFL can have a difference from a threshold voltage in the region RG1 of only 100 mV depending on a design. In this case, although it is difficult to observe a clear inflection point as shown in FIG. 8, an effect of the tailed distribution PFL can be obtained.

According to Embodiment 1, the histogram (FIG. 5) has the distribution tailed on the low voltage side contiguously with the normal distribution. A rapid rise of a current in turn-on of the semiconductor device 101 is thereby suppressed. In other words, di/dt (a time-derivative of the current) can be reduced. Radiated noise from the semiconductor device 101 can thus be suppressed. On the other hand, a significant increase in conduction loss due to the tailed distribution PFL can be avoided by making a ratio of the region RG1 occupying the largest area in the active IGBT cell region 10 (FIG. 1) sufficiently increased. A ratio of a total occupied area of regions other than the region RG1 to an occupied area of the region RG1 in FIG. 5 may be in a range of 1:10 to 1:10⁷, for example. Even if the ratio of the total occupied area of the regions other than the region RG1 is suppressed to a small value of 1/10⁷, a current on the order of 10⁻⁷ A (100 nA) flows due to the tailed distribution PFL by applying the tailed distribution PFL in a typical IGBT having a saturation current of approximately several amperes, and the presence of the tailed distribution PFL can easily be determined from a waveform of transfer characteristics.

FIG. 9 is a graphical illustration of a histogram of a distribution of threshold voltages in a plan layout of a semiconductor device 102 according to Embodiment 2. The histogram (FIG. 9) of the semiconductor device 102 includes the substantially normal distribution PNM (a coarsely hatched region in FIG. 9) similarly to the histogram (FIG. 2) of the semiconductor device 100P while having a distribution skewed toward a high voltage side contiguously with the normal distribution PNM. Specifically, the histogram of the semiconductor device 102 has, in addition to the normal distribution PNM, a tailed distribution PFH (a finely hatched region in FIG. 9) being a distribution tailed on the high voltage side. In other words, the histogram has, based on the normal distribution PNM, the tailed distribution PFH tailed on the high voltage side contiguously with the normal distribution PNM. In contrast to the histogram of the semiconductor device 100Q (FIG. 4), the histogram of the semiconductor device 102 (FIG. 9) does not include one or more bins each having a frequency of zero interposed between bins each having a frequency being not zero. In FIG. 9, the tailed distribution PFH overlaps the normal distribution PNM on the high voltage side to form the distribution of the histogram. The histogram is thus contiguous.

In an example shown in FIG. 9, the region RG8 being the highest voltage portion of the tailed distribution PFH does not overlap the normal distribution PNM. The highest voltage portion of the distribution of the histogram thus only includes the tailed distribution PFH. On the other hand, the region RG4 being the highest voltage portion of the normal distribution PNM overlaps the tailed distribution PFH.

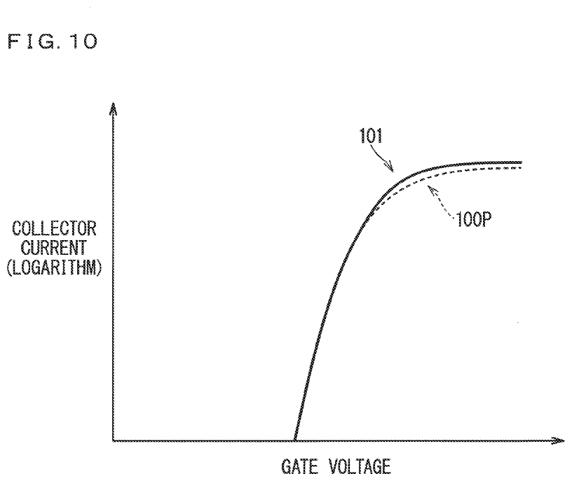

Referring to FIG. 10, a solid line in a graph indicates one example of transfer characteristics of the semiconductor device 102 (FIG. 9), and a dashed line in the graph indicates one example of transfer characteristics of the semiconductor device 100P (FIG. 2). The semiconductor device 102 (FIG. 9) has the tailed distribution PFH on the high voltage side, and, due to the tailed distribution PFH, a waveform different from the dashed line (the semiconductor device 100P according to the comparative example) appears near the saturation current. Cells in regions corresponding to the tailed distribution PFH are turned off first in off operation. Sweeping out of carriers is thus promoted compared with that in the semiconductor device 100P according to the comparative example.

According to Embodiment 2, the histogram (FIG. 9) has the distribution tailed on the high voltage side contiguously with the normal distribution. Ejection of minority carriers when the semiconductor device 102 is turned off is thus promoted. A turn-off loss of the semiconductor device 102 can thus be reduced. In a case where the histogram of the threshold voltages changes contiguously as shown in FIG. 9, rapid off operation of a chip (i.e., a single semiconductor substrate) forming the semiconductor device 102 as a whole is less likely to occur, so that an effect of suppressing voltage surges can be obtained.

A ratio of a total occupied area of the tailed distribution PFH to a total occupied area of the normal distribution PNM in FIG. 9 may be in a range of 1:10 to 1:10⁷, for example. When the ratio of the total occupied area of the tailed distribution PFH is suppressed to a small value of 1/10⁷, it is sometimes difficult to determine the presence or absence of the tailed distribution PFH from the transfer characteristics (see FIG. 10). Also in this case, the presence or absence of the tailed distribution PFH can be determined through heat generation analysis. Specifically, in a case where there is a region having a high threshold voltage within the chip when the gate voltage is increased in steps of several millivolts, for example, the amount of energization is small only in this portion, so that heat generation is suppressed. That is to say, there is a distribution within the chip in a result of heat generation analysis. Heat generation analysis is generally technology enabling analysis of a failed portion at a unit cell level and thus can be used to determine a region having a different threshold voltage even in a small region having a ratio of 1/10⁷. Heat generation analysis is thus a useful means of determining whether the configuration in Embodiment 2 is applied. Luminescence analysis is similarly a useful means. Whether the configuration in Embodiment 1 is applied can also be determined using a similar method.

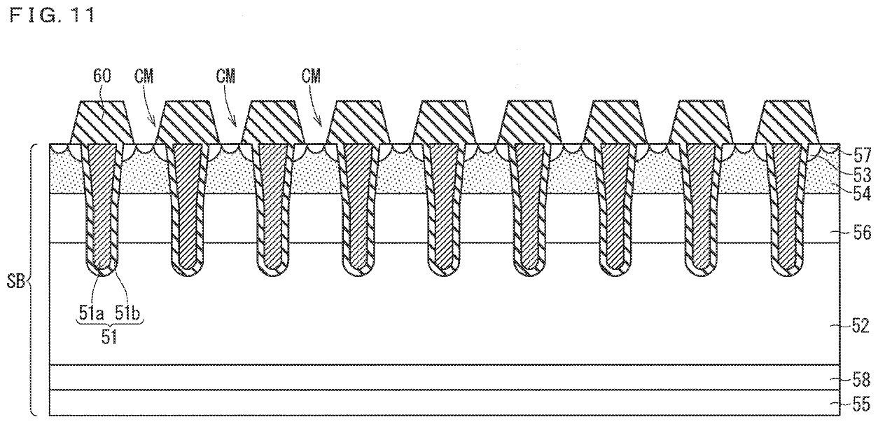

FIG. 11 is a cross-sectional view illustrating a specific configuration of the active IGBT cell region 10 (see FIG. 1) of a semiconductor device corresponding to a typical trench-gate IGBT. The semiconductor device includes cells CM having substantially similar design configurations in contrast to that in Embodiment 1 or 2. In light of manufacturing variations and the like, a histogram of the semiconductor device has the normal distribution PNM similarly to the histogram of the semiconductor device 100P (FIG. 2).

In the active IGBT cell region 10 (see FIG. 1) of the semiconductor device (FIG. 11), the semiconductor substrate SB has an upper surface (a first main surface) and a lower surface (second main surface). A portion of the upper surface of the semiconductor substrate SB includes an n⁺ type source layer 53 and a p⁺ contact layer 57. At least portion of the lower surface of the semiconductor substrate SB includes a p type collector layer 55. An n⁻ drift layer 52 is included between the upper surface and the lower surface. An n⁺ buffer layer 58 is included between the n⁻ drift layer 52 and the p type collector layer 55. A charge storage layer (CS layer) 56 is included on the n″ drift layer 52 between the n⁻ drift layer 52 and the upper surface. The CS layer 56 has a higher impurity concentration than the drift layer 52. A p type base layer 54 is included between the CS layer 56 and the upper surface. The n⁺ type source layer 53 and the p⁺ contact layer 57 are included between the p type base layer 54 and the upper surface.

The semiconductor substrate SB also includes, for switching of the semiconductor device, a gate structure 51 extending from the upper surface through the p type base layer 54 and the CS layer 56. The gate structure 51 includes a gate electrode 51a and a gate dielectric film 51b being in contact with each other. In a trench filled with the gate structure 51, the gate dielectric film 51b is in contact with the n⁻ drift layer 52, the n⁺ type source layer 53, the p type base layer 54, and the CS layer 56. The gate dielectric film 51b is an oxide film, for example. An interlayer dielectric film 60 is provided on the upper surface of the semiconductor substrate SB to insulate between the gate electrode 51a and an emitter electrode (not illustrated in FIG. 11) provided on the upper surface of the semiconductor substrate SB. A collector electrode (not illustrated) is provided on the lower surface of the semiconductor substrate SB.

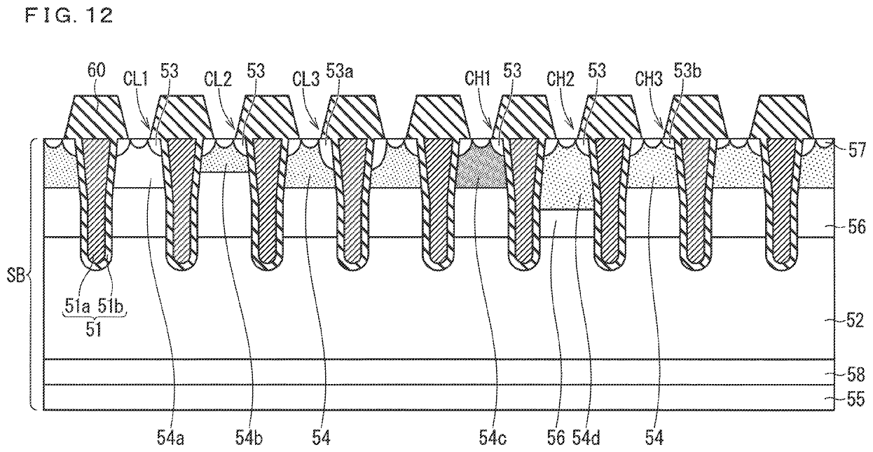

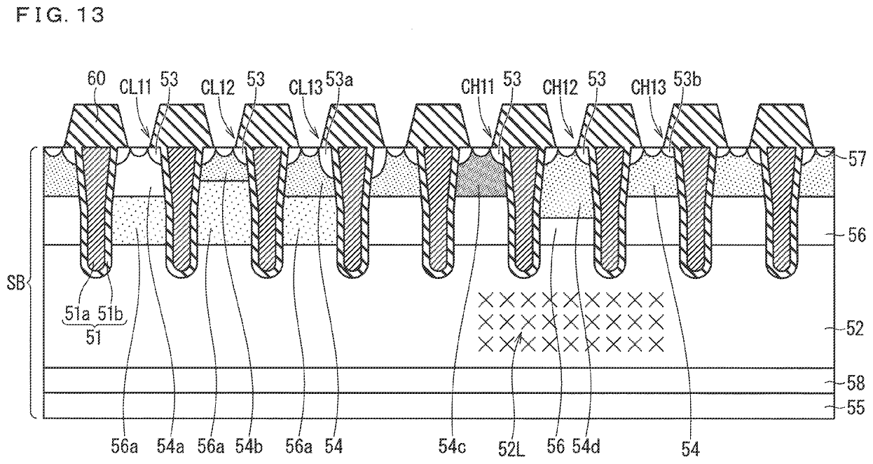

The semiconductor device 101 or the semiconductor device 102 described above can be obtained by replacing one or more of the plurality of cells CM of the above-mentioned semiconductor device with at least one type of cells each having a different threshold voltage as appropriate. A structure of the cells therefor will be described below with reference to FIG. 12 or FIG. 13.

Referring to FIG. 12, cells CL1 to CL3 each have a lower threshold voltage and cells CH1 to CH3 each have a higher threshold voltage than the cells CM (FIG. 11).

A p type base layer 54a of the cell CL1 has a lower impurity concentration than the p type base layer 54 of each of the cells CM (FIG. 11). In contrast, a p type base layer 54c of the cell CH1 has a higher impurity concentration than the p type base layer 54 of each of the cells CM (FIG. 11). The distribution of threshold voltages of the semiconductor device can be controlled by applying at least one of the cell CL1 and the cell CH1. In other words, the p type base layer may have a distribution of impurity concentrations in a plan layout corresponding to the distribution of threshold voltages required for the semiconductor device.

A p type base layer 54b of the cell CL2 has a depth from the upper surface of the semiconductor substrate SB less than that of the p type base layer 54 of each of the cells CM (FIG. 11). A p type base layer 54d of the cell CH2 has a depth from the upper surface of the semiconductor substrate SB more than that of the p type base layer 54 of each of the cells CM (FIG. 11). The distribution of threshold voltages of the semiconductor device can be controlled by applying at least one of the cell CL2 and the cell CH2. In other words, the p type base layer may have a distribution of depths in the plan layout corresponding to the distribution of threshold voltages required for the semiconductor device.

An n⁺ type source layer 53a of the cell CL3 has a depth from the upper surface of the semiconductor substrate SB more than that of the n⁺ type source layer 53 of each of the cells CM (FIG. 11). An n⁺ type source layer 53b of the cell CH3 has a depth from the upper surface of the semiconductor substrate SB less than that of the n⁺ type source layer 53 of each of the cells CM (FIG. 11). The distribution of threshold voltages of the semiconductor device can be controlled by applying at least one of the cell CL3 and the cell CH3. In other words, the n⁺ type source layer may have a distribution of depths in the plan layout corresponding to the distribution of threshold voltages required for the semiconductor device.

A threshold voltage of each of the cells can be reduced by reducing the thickness of the gate dielectric film 51b and can be increased by increasing the thickness of the gate dielectric film 51b. The distribution of threshold voltages of the semiconductor device can be controlled by applying such a cell. In other words, the gate dielectric film 51b may have a distribution of thicknesses in the plan layout corresponding to the distribution of threshold voltages.

The threshold voltage of each of the cells can also be controlled by a plane orientation of a channel of the gate structure 51. Description will be made below in this respect. The p type base layer 54 of the semiconductor substrate SB includes, as a channel region, a portion facing the gate structure 51 on an inner wall of the trench. The threshold voltage has a dependence on a plane orientation (crystallographic Si plane orientation in a case where the semiconductor substrate SB is an Si substrate) of the portion. The distribution of threshold voltages of the semiconductor device can thus be controlled by applying a cell having a different plane orientation of the portion from each of the cells CM (FIG. 11). In other words, the portion facing the gate structure 51 of the p type base layer 54 may have a distribution of plane orientations in the plan layout corresponding to the distribution of threshold voltages.

The threshold voltage of each of the cells can also be controlled by an internal stress of the semiconductor substrate SB. In other words, the semiconductor substrate SB may have a distribution of internal stresses in the plan layout corresponding to the distribution of threshold voltages. An intrinsic internal stress in a channel region of a semiconductor generally has a relationship with an interatomic distance, and it is known that a change in interatomic distance causes a change in band gap to easily change the threshold voltage. The internal stress is controlled by heat treatment to mitigate ion implantation damage, a formation condition of a gate oxide film, a film type or a formation condition of the interlayer dielectric film, a formation condition of the emitter electrode, a formation condition of a glass coat film, a formation condition of a polyimide coat film, and the like. A formation condition of each element herein includes conditions on a temperature during formation, a formation speed, a thickness of a formed film, or heat treatment after formation, for example.

FIG. 13 is a cross-sectional view illustrating cells CL11 to CL13 and cells CH11 to CH13 as modifications of the cells CL1 to CL3 and the cells CH1 to CH3 in FIG. 12.

In an example illustrated in FIG. 13, the drift layer 52 of the semiconductor substrate SB incudes a lifetime control layer 52L in the cells CH11 to CH13. Thus, in the semiconductor device to which the cells CH11 to CH13 have been applied, the plurality of regions RG1 to RGn can include a region in which the lifetime control layer 52L is disposed and a region in which the lifetime control layer 52L is not disposed. Providing the lifetime control layer 52L as appropriate smooths ejection of minority carriers and reduces the turn-off loss.

In the example illustrated in FIG. 13, the charge storage layer 56 (FIG. 12) of the semiconductor substrate SB is selectively adjusted. Specifically, charge storage layers 56a of the cells CL11 to CL13 each have a different impurity concentration from the charge storage layer 56 of each of the cells CM (FIG. 11). Thus, in the semiconductor device to which the cells CL11 to CL13 have been applied, the plurality of regions RG1 to RGn can have a difference in impurity concentration of the charge storage layer. Adjustment of the distribution of impurity concentrations of the charge storage layer as described above smooths ejection of minority carriers and reduces the turn-off loss.

As described above, the semiconductor device 101 or the semiconductor device 102 described above can be obtained by applying at least one type of the above-mentioned various cells each having a different threshold voltage from each of the cells CM (FIG. 11). A cell having characteristics of two or more of the plurality of types of cells may be applied.

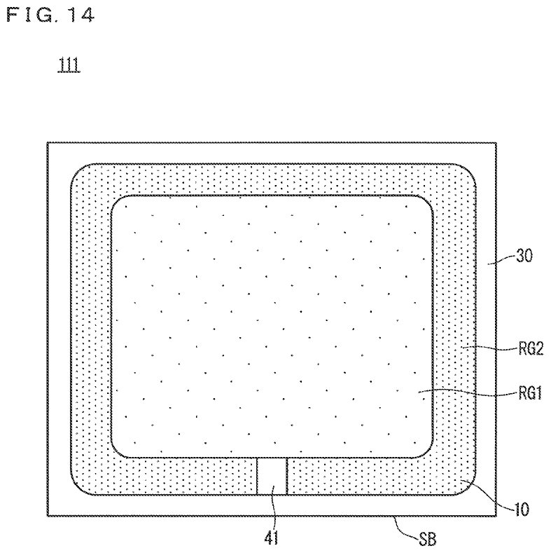

FIG. 14 is a plan view illustrating a configuration of a plan layout on the semiconductor substrate SB of a semiconductor device 111 according to a modification of FIG. 6. In the semiconductor device 111, the largest region RG1 of all the plurality of regions RG1 to RGn (the regions RG1 and RG2 in the illustrated example) of the plan layout includes a center of the semiconductor substrate SB. The region RG2 roughly surrounds the region RG1. In the illustrated example, the region RG2 and the gate pad region 41 surround the region RG1.

Advantages of the semiconductor device 111 will be described below for each of a case where the threshold voltage is higher in the region RG1 than in the region RG2 and a case where the threshold voltage is lower in the region RG1 than in the region RG2.

First, in a case where the threshold voltage is higher in the region RG1, the turn-off loss at the center of the semiconductor substrate SB can be reduced. Heat is generally most accumulated at the center of a chip of an IGBT during steady operation, so that a heat distribution of the semiconductor device 111 can be equalized by reducing the turn-off loss at the center. An effect of equalization is particularly noticeable during fast switching. Equalization of the heat distribution improves a wear life of the semiconductor device 111.

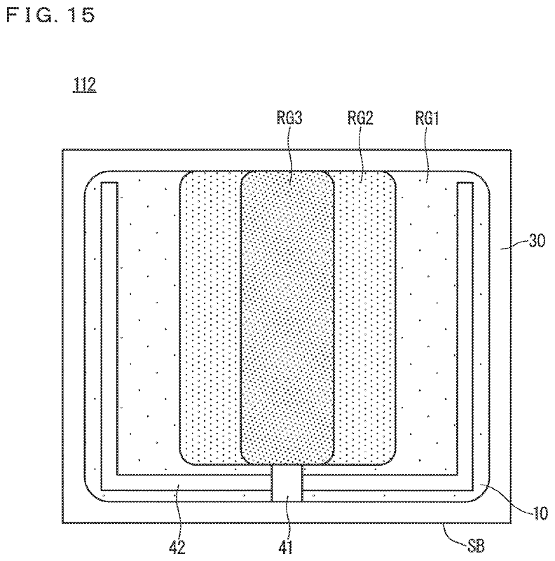

Second, in a case where the threshold voltage is lower in the region RG1, a switching speed can be increased at the center likely to have a long distance from a gate wire 42 (see FIG. 15). A gate signal of the IGBT generally tends to be delayed before reaching the center of the semiconductor substrate SB. The threshold voltage in the region RG1 at the center of the semiconductor substrate SB is thus designed to be low to compensate for the delay. This enables uniform switching within the chip as a whole. An increase in short circuit capability can thus be expected.

According to the semiconductor device 111, one of the above-mentioned two effects can be obtained in each of a case where the threshold voltage is higher in the region RG1 than in the region RG2 and a case where the threshold voltage is lower in the region RG1 than in the region RG2.

FIG. 15 is a plan view illustrating a configuration of a plan layout on the semiconductor substrate SB of a semiconductor device 112 according to a modification of FIG. 6. The semiconductor device 112 includes the gate wire 42 disposed on the semiconductor substrate SB. The gate wire 42 is to apply a potential applied to the gate pad region 41 for switching to the gate electrode 51a (see FIG. 11). The gate wire 42 includes a portion extending along one direction (a vertical direction in FIG. 15). A boundary between adjacent regions of the plurality of regions RG1 to RG3 of the plan layout, that is, a boundary between the region RG1 and the region RG2 and a boundary between the region RG2 and a region RG3 each include a portion extending along the above-mentioned one direction (vertical direction in FIG. 15).

According to the present modification, in a case where the boundary between adjacent regions of the plurality of regions RG1 to RG3 of the plan layout includes the portion extending along the one direction, the regions RG1 to RG3 are arranged according to a distance from the portion of the gate wire extending along the one direction. In this case, if the threshold voltage is distributed to increase with increasing distance from the portion of the gate wire, the turn-off loss can be reduced by delaying switching in a portion farther from the portion of the gate wire. If the threshold voltage is distributed to decrease with increasing distance from the portion of the gate wire, a timing of switching within the chip can be more equalized.

Specifically, the semiconductor substrate SB has a substantially rectangular shape, and at least portion of the above-mentioned boundary extends along a long side or a short side (short side in an example of FIG. 15) thereof. The gate wire 42 is generally disposed in parallel with the long side or the short side of the chip. The gate signal transmitted from the gate wire 42 is generally characterized by arriving early at a location close to the gate wire 42 and arriving late at a location farther from the gate wire 42. The characteristics lead to an effect of suppressing the turn-off loss. When the distribution of threshold voltages is set so that the threshold voltage increases with increasing distance from the gate wire 42, the above-mentioned effect can be enhanced. In contract, when the distribution of threshold voltages is set so that the threshold voltage decreases with increasing distance from the gate wire 42, uniform switching within the chip can be performed by compensating for the delay of signal transmission dependent on the distance from the gate wire 42.

It is an object of the semiconductor device 112 to obtain the above-mentioned effect by providing the distribution of threshold voltages according to the distance from a main portion (vertically extending portion in FIG. 15) of the gate wire 42. The above-mentioned boundary extends substantially along the above-mentioned long side or short side (more generally the above-mentioned one direction) to the extent that the effect can sufficiently be obtained. The above-mentioned one direction is not necessarily limited to a direction along the long side or the short side of the semiconductor substrate SB. For example, the above-mentioned one direction may be a direction of extension of a termination electrode pattern on the semiconductor substrate SB.

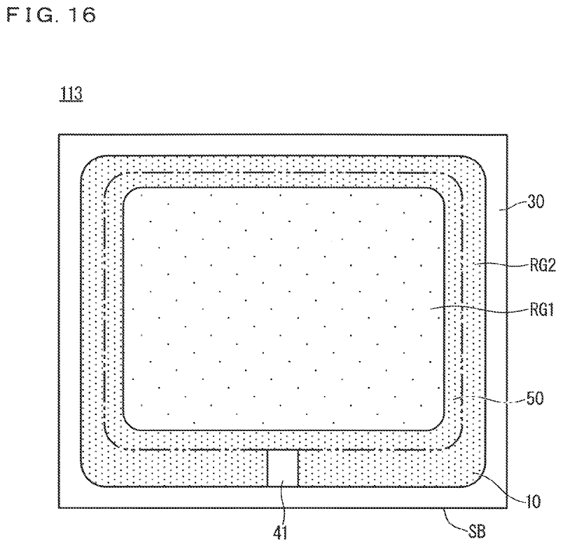

FIG. 16 is a plan view illustrating a configuration of a plan layout on the semiconductor substrate SB of a semiconductor device 113 according to a modification of FIG. 6. Only an edge of an emitter electrode 50 disposed on the semiconductor substrate SB is indicated by an alternate long and two short dashes line. The plurality of regions RG1 to RGn of the plan layout include the largest region RG1 of all the regions and the region RG2 (more generally at least one region) having a higher threshold voltage than the region RG1. In the plan layout, at least portion of the edge of the emitter electrode 50 is disposed in the region RG2. As illustrated, almost all the edge of the emitter electrode 50 may be disposed in the region RG2. The region RG2 (more generally at least one region other than the region RG1) may extend along the edge of the emitter electrode 50.

According to the present modification, the short circuit capability can be increased. Short-circuit breakdown is generally likely to occur at the edge of the emitter electrode 50 where currents concentrate. Current concentration during short-circuit can thus be suppressed by forming the region RG2 having a higher threshold voltage along the edge of the emitter electrode 50.

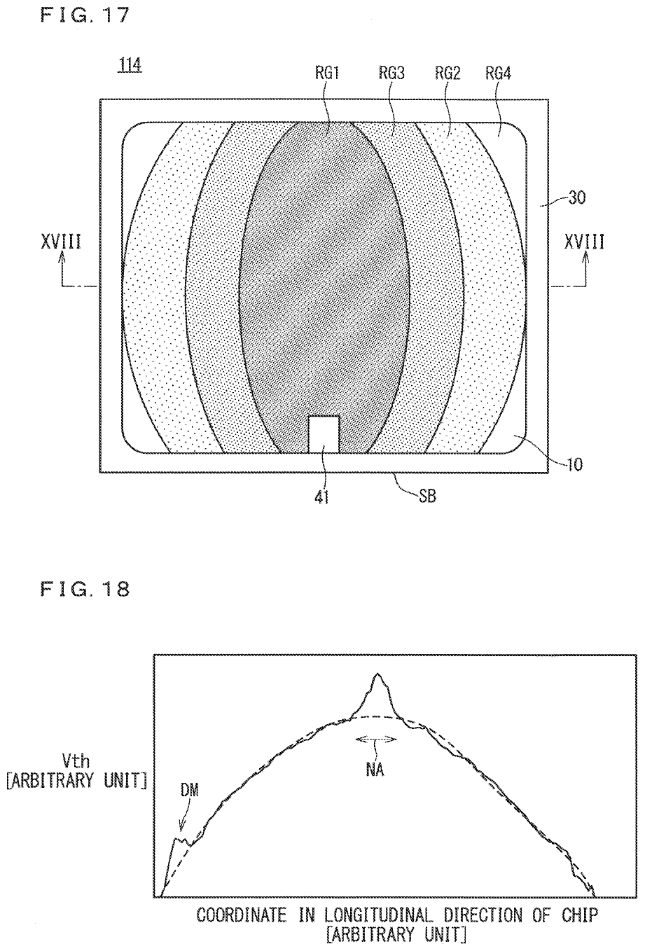

FIG. 17 is a plan view illustrating a configuration of a plan layout on the semiconductor substrate SB of a semiconductor device 114 according to a modification of FIG. 6. In the plan layout, the semiconductor substrate SB has a rectangular shape having a long side and a short side. In the plan layout, the boundary between adjacent regions of the plurality of regions RG1 to RGn extends along at least portion of an ellipse. A major axis of the above-mentioned ellipse extends along the short side of the rectangular shape (a vertical direction in FIG. 17). The above-mentioned ellipse thus has a pair of foci (not illustrated) opposing in a direction along the short side.

The boundary between adjacent regions of the plurality of regions RG1 to RGn is only required to extend substantially along at least portion of the ellipse and is not necessarily required to extend completely along a geometrically strict ellipse. The above-mentioned ellipse has a closed curve shape that is symmetric in each of an X direction and a Y direction in an XY coordinate system in the plan layout. The above-mentioned boundary is thus also substantially symmetric in each of the X direction and the Y direction. An axis of symmetry may pass through an approximate center of the semiconductor substrate SB.

The regions RG1 to RGn as illustrated in FIG. 17 can be obtained by a bow of the substrate. FIG. 18 is a graphical illustration of one contemplated example of the distribution of threshold voltages Vth taken along the line XVIII-XVIII of FIG. 17. A solid line in the graph is a line obtained by contemplating results of measurement of a bow amount of the semiconductor substrate SB and converting the results into the threshold voltages Vth. A range NA is different from a region other than the active cell region of the semiconductor substrate SB. Contemplated measurement variations DM are also shown. A dashed line in the graph is an approximate line in a case where the effects of the range NA and the measurement variations DM are excluded. According to the approximate line, the distribution of threshold voltages along a longitudinal direction of the chip has an axis of symmetry at the approximate center of the semiconductor substrate SB. Although not illustrated, the distribution of threshold voltages along a transverse direction of the chip also has an axis of symmetry at the approximate center of the semiconductor substrate SB.

Embodiments can freely be combined with each other and can be modified or omitted as appropriate.

### APPENDICES

Various aspects of the present disclosure will collectively be described below as appendices.

### APPENDIX 1

A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching, and
in a case where a histogram is defined by a plurality of bins each having a bin width of 100 mV for the threshold voltages and a plurality of frequencies corresponding to areas in the plan layout belonging to the respective bins, the plan layout includes a plurality of regions belonging to different bins of the plurality of bins, the plurality of regions include first to third regions, and the histogram has, based on a normal distribution, a distribution tailed on a low voltage side contiguously with the normal distribution.

### APPENDIX 2

A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching, and
in a case where a histogram is defined by a plurality of bins each having a bin width of 100 mV for the threshold voltages and a plurality of frequencies corresponding to areas in the plan layout belonging to the respective bins, the plan layout includes a plurality of regions belonging to different bins of the plurality of bins, the plurality of regions include first to third regions, and the histogram has, based on a normal distribution, a distribution tailed on a high voltage side contiguously with the normal distribution.

### APPENDIX 3

The semiconductor device according to Appendix 1 or 2, wherein
the semiconductor substrate further includes a base layer having a second conductivity type different from the first conductivity type, and
the base layer has a distribution of impurity concentrations in the plan layout corresponding to the distribution of the threshold voltages.

### APPENDIX 4

The semiconductor device according to Appendix 1 or 2, wherein
the semiconductor substrate further includes a base layer having a second conductivity type different from the first conductivity type, and
the base layer has a distribution of depths in the plan layout corresponding to the distribution of the threshold voltages.

### APPENDIX 5

The semiconductor device according to Appendix 1 or 2, wherein
the semiconductor substrate further includes a source layer having the first conductivity type, and
the source layer has a distribution of depths in the plan layout corresponding to the distribution of the threshold voltages.

### APPENDIX 6

The semiconductor device according to Appendix 1 or 2, wherein
the gate dielectric film has a distribution of thicknesses in the plan layout corresponding to the distribution of the threshold voltages.

### APPENDIX 7

The semiconductor device according to Appendix 1 or 2, wherein
the semiconductor substrate has a trench filled with the gate structure, and
the semiconductor substrate further includes a base layer having a second conductivity type different from the first conductivity type and including a portion facing the gate structure, the portion facing the gate structure having a distribution of plane orientations in the plan layout corresponding to the distribution of the threshold voltages.

### APPENDIX 8

The semiconductor device according to any one of Appendices 1 to 7, wherein
the largest region of all the plurality of regions of the plan layout includes a center of the semiconductor substrate.

### APPENDIX 9

The semiconductor device according to any one of Appendices 1 to 7, further comprising
a gate wire disposed on the semiconductor substrate, including a portion extending along one direction, and to apply a potential for the switching to the gate electrode, wherein
a boundary between adjacent regions of the plurality of regions of the plan layout includes a portion extending along the one direction.

### APPENDIX 10

The semiconductor device according to any one of Appendices 1 to 7, further comprising
an emitter electrode having an edge, the emitter electrode being disposed on the semiconductor substrate, wherein
the plurality of regions include the first region being the largest region of all the plurality of regions and at least one region having a higher threshold voltage than the first region, and
in the plan layout, at least portion of the edge of the emitter electrode is disposed in the at least one region.

### APPENDIX 11

The semiconductor device according to any one of Appendices 1 to 7, wherein
in the plan layout, the semiconductor substrate has a rectangular shape having a long side and a short side, and
in the plan layout, a boundary between adjacent regions of the plurality of regions extends along at least portion of an ellipse having a major axis along the short side of the rectangular shape.

### APPENDIX 12

A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching, and
in a case where a plurality of bins each having a bin width of 100 mV for the threshold voltages are defined, the plan layout includes a plurality of regions belonging to different bins of the plurality of bins, and
the largest region of all the plurality of regions of the plan layout includes a center of the semiconductor substrate.

### APPENDIX 13

A semiconductor device being an insulated gate bipolar transistor or a reverse-conducting insulated gate bipolar transistor, the semiconductor device comprising:
a semiconductor substrate including a drift layer having a first conductivity type;
a gate structure including a gate electrode and a gate dielectric film for switching of the semiconductor device; and
a gate wire disposed on the semiconductor substrate, including a portion extending along one direction, and to apply a potential for the switching to the gate electrode, wherein
a plan layout on the semiconductor substrate has a distribution of threshold voltages for the switching,
in a case where a plurality of bins each having a bin width of 100 mV for the threshold voltages are defined, the plan layout includes a plurality of regions belonging to different bins of the plurality of bins, and
a boundary between adjacent regions of the plurality of regions of the plan layout includes a portion extending along the one direction.

### APPENDIX 14

A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
the semiconductor device further comprises, on the semiconductor substrate, an emitter electrode having an edge,
a plan layout on the semiconductor substrate has a distribution of threshold voltages for the switching,
in a case where a plurality of bins each having a bin width of 100 mV for the threshold voltages are defined, the plan layout includes a plurality of regions belonging to different bins of the plurality of bins,
the plurality of regions include the first region being the largest region of all the plurality of regions and at least one region having a higher threshold voltage than the first region, and
in the plan layout, at least portion of the edge of the emitter electrode is disposed in the at least one region.

### APPENDIX 15

A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching,
in a case where a plurality of bins each having a bin width of 100 mV for the threshold voltages are defined, the plan layout includes a plurality of regions belonging to different bins of the plurality of bins,
the semiconductor device further comprises, on the semiconductor substrate, an emitter electrode having an edge,
the plurality of regions include the largest region of all the plurality of regions and at least one region,
in the plan layout, the semiconductor substrate has a rectangular shape having a long side and a short side, and
in the plan layout, a boundary between adjacent regions of the plurality of regions extends along at least portion of an ellipse having a major axis along the short side of the rectangular shape.

### APPENDIX 16

The semiconductor device according to any one of Appendices 1, 2 and 12 to 15, wherein
the semiconductor substrate has a distribution of internal stresses in the plan layout corresponding to the distribution of the threshold voltages.

### APPENDIX 17

The semiconductor device according to any one of Appendices 1 to 16, wherein
the semiconductor substrate further includes, on the drift layer, a charge storage layer having the first conductivity type and having a higher impurity concentration than the drift layer, and
the plurality of regions include a plurality of regions differing in impurity concentration of the charge storage layer.

### APPENDIX 18

The semiconductor device according to any one of Appendices 1 to 16, wherein
the drift layer of the semiconductor substrate includes a lifetime control layer, and
the plurality of regions include a region in which the lifetime control layer is disposed and a region in which the lifetime control layer is not disposed.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching, and
in a case where a histogram is defined by a plurality of bins each having a bin width of 100 mV for the threshold voltages and a plurality of frequencies corresponding to areas in the plan layout belonging to the respective bins, the plan layout includes a plurality of regions belonging to different bins of the plurality of bins, the plurality of regions include first to third regions, and the histogram has, based on a normal distribution, a distribution tailed on a low voltage side or on a high voltage side contiguously with the normal distribution.

2. The semiconductor device according to claim 1, wherein
the semiconductor substrate further includes a base layer having a second conductivity type different from the first conductivity type, and
the base layer has a distribution of impurity concentrations in the plan layout corresponding to the distribution of the threshold voltages.

3. The semiconductor device according to claim 1, wherein
the semiconductor substrate further includes a base layer having a second conductivity type different from the first conductivity type, and
the base layer has a distribution of depths in the plan layout corresponding to the distribution of the threshold voltages.

4. The semiconductor device according to claim 1, wherein
the semiconductor substrate further includes a source layer having the first conductivity type, and
the source layer has a distribution of depths in the plan layout corresponding to the distribution of the threshold voltages.

5. The semiconductor device according to claim 1, wherein
the gate dielectric film has a distribution of thicknesses in the plan layout corresponding to the distribution of the threshold voltages.

6. The semiconductor device according to claim 1, wherein
the semiconductor substrate has a trench filled with the gate structure, and
the semiconductor substrate further includes a base layer having a second conductivity type different from the first conductivity type and including a portion facing the gate structure, the portion facing the gate structure having a distribution of plane orientations in the plan layout corresponding to the distribution of the threshold voltages.

7. The semiconductor device according to claim 1, wherein
the largest region of all the plurality of regions of the plan layout includes a center of the semiconductor substrate.

8. The semiconductor device according to claim 1, further comprising
a gate wire disposed on the semiconductor substrate, including a portion extending along one direction, and to apply a potential for the switching to the gate electrode, wherein
a boundary between adjacent regions of the plurality of regions of the plan layout includes a portion extending along the one direction.

9. The semiconductor device according to claim 1, further comprising
an emitter electrode having an edge, the emitter electrode being disposed on the semiconductor substrate, wherein
the plurality of regions include the first region being the largest region of all the plurality of regions and at least one region having a higher threshold voltage than the first region, and
in the plan layout, at least portion of the edge of the emitter electrode is disposed in the at least one region.

10. The semiconductor device according to claim 1, wherein
in the plan layout, the semiconductor substrate has a rectangular shape having a long side and a short side, and
in the plan layout, a boundary between adjacent regions of the plurality of regions extends along at least portion of an ellipse having a major axis along the short side of the rectangular shape.

11. The semiconductor device according to claim 1, wherein
the semiconductor substrate has a distribution of internal stresses in the plan layout corresponding to the distribution of the threshold voltages.

12. The semiconductor device according to claim 1, wherein
the semiconductor substrate further includes, on the drift layer, a charge storage layer having the first conductivity type and having a higher impurity concentration than the drift layer, and
the plurality of regions include a plurality of regions differing in impurity concentration of the charge storage layer.

13. The semiconductor device according to claim 1, wherein
the drift layer of the semiconductor substrate includes a lifetime control layer, and
the plurality of regions include a region in which the lifetime control layer is disposed and a region in which the lifetime control layer is not disposed.

14. A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching, and
in a case where a plurality of bins each having a bin width of 100 mV for the threshold voltages are defined, the plan layout includes a plurality of regions belonging to different bins of the plurality of bins, and
the largest region of all the plurality of regions of the plan layout includes a center of the semiconductor substrate.

15. A semiconductor device being an insulated gate bipolar transistor or a reverse-conducting insulated gate bipolar transistor, the semiconductor device comprising:
a semiconductor substrate including a drift layer having a first conductivity type;
a gate structure including a gate electrode and a gate dielectric film for switching of the semiconductor device; and
a gate wire disposed on the semiconductor substrate, including a portion extending along one direction, and to apply a potential for the switching to the gate electrode, wherein
a plan layout on the semiconductor substrate has a distribution of threshold voltages for the switching,
in a case where a plurality of bins each having a bin width of 100 mV for the threshold voltages are defined, the plan layout includes a plurality of regions belonging to different bins of the plurality of bins, and
a boundary between adjacent regions of the plurality of regions of the plan layout includes a portion extending along the one direction.

16. A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
the semiconductor device further comprises, on the semiconductor substrate, an emitter electrode having an edge,
a plan layout on the semiconductor substrate has a distribution of threshold voltages for the switching,
in a case where a plurality of bins each having a bin width of 100 mV for the threshold voltages are defined, the plan layout includes a plurality of regions belonging to different bins of the plurality of bins,
the plurality of regions include the first region being the largest region of all the plurality of regions and at least one region having a higher threshold voltage than the first region, and
in the plan layout, at least portion of the edge of the emitter electrode is disposed in the at least one region.

17. A semiconductor device being an insulated gate bipolar transistor or a reverse-conducting insulated gate bipolar transistor, the semiconductor device comprising:
a semiconductor substrate including a drift layer having a first conductivity type; and
a gate structure including a gate electrode and a gate dielectric film for switching of the semiconductor device, wherein
a plan layout on the semiconductor substrate has a distribution of threshold voltages for the switching,
in a case where a plurality of bins each having a bin width of 100 mV for the threshold voltages are defined, the plan layout includes a plurality of regions belonging to different bins of the plurality of bins,
the semiconductor device further comprises, on the semiconductor substrate, an emitter electrode having an edge,
the plurality of regions include the largest region of all the plurality of regions and at least one region,
in the plan layout, the semiconductor substrate has a rectangular shape having a long side and a short side, and
in the plan layout, a boundary between adjacent regions of the plurality of regions extends along at least portion of an ellipse having a major axis along the short side of the rectangular shape.
